(19) United States
(12) Patent Application Publication
(10) Pub. No.: US 2008/0079060 A1
(43) Pub. Date: Apr. 3, 2008

(54) DUAL FUNCTION FINFET STRUCTURE AND METHOD FOR FABRICATION THEREOF

(75) Inventor: Huilong Zhu, Poughkeepsie, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/307,295

(22) Filed: Jan. 31, 2006

(51) Int. Cl. H01L 29/786; H01L 21/336

(52) U.S. Cl. 257/321; 438/157; 257/E29.3; 257/E21.411

(57) ABSTRACT

A dual function finFET structure includes a semiconductor fin located over a substrate. The semiconductor fin has a first side and a second side opposite the first side. A gate dielectric layer is located laterally adjoining the first side of the semiconductor fin, and a control gate is located further laterally adjoining the gate dielectric layer. A tunneling dielectric layer is located laterally adjoining the second side of the semiconductor fin. A floating gate is located further laterally adjoining the tunneling dielectric layer, an intergate dielectric layer is located further laterally adjoining the floating gate and a storage/programming gate is located further laterally adjoining the intergate dielectric layer. To enhance performance, the control gate has a narrower linewidth than the storage/programming gate.

### BACKGROUND

1. Field of the Invention

The invention relates generally to finFET devices. More particularly, the invention relates to finFET devices with enhanced functionality.

2. Description of the Related Art

finFET devices are semiconductor devices that comprise a semiconductor fin located edgewise upon a substrate. Each vertical surface of the semiconductor fin includes a gate dielectric which is optionally contiguously located upon a top surface of the semiconductor fin. An inverted U shaped gate electrode often straddles a central section of the semiconductor fin and covers the gate dielectric layers. In other instances, a portion of a gate electrode is not located atop the semiconductor fin, and thus a pair of gate electrodes is restricted to the sidewalls of the semiconductor fin. End portions of the semiconductor fin, uncovered by the gate electrode, are typically subject to ion implantation while using the gate electrode or other masking layer as a mask, to thus provide source/drain regions within the semiconductor fin that are separated by a channel region located beneath or covered by the gate electrode within the semiconductor fin.

finFET devices provide several advantages in comparison with conventional planar field effect transistor devices. In particular, since finFET devices are vertical channel devices they may be scaled effectively in the vertical direction while not using any additional semiconductor substrate area. Thus, finFET devices offer an opportunity for enhanced semiconductor device performance absent an increase in aerial dimensions.

finFET devices also provide a novel alternative structure that allows for enhanced control of short channel effects (SCEs) when a gate electrode length within a MOSFET is otherwise aggressively scaled to a smaller length. However, a need continues to exist within the semiconductor fabrication art for novel semiconductor device structures that provide not only enhanced control of an SCE, but also enhanced semiconductor device functionality.

In that regard, and although not specifically related to finFET devices, Kumar, in U.S. Pat. No. 6,445,032, teaches an electrically erasable programmable read only memory (EEPROM) semiconductor device that comprises a first gate electrode and a first gate dielectric layer covering a channel region within a semiconductor substrate, as well as a second gate electrode and a second gate dielectric layer covering a different portion of the channel. To achieve the foregoing geometric result, the second gate electrode is located in a back plane with respect to the first gate electrode. The different locations of the first gate electrode and the second gate electrode allow the first gate dielectric layer to be separately scaleable from the second gate dielectric layer. Also, the electrically erasable programmable read only memory (EEPROM) semiconductor device may include both logic functionality and memory functionality.

The space efficiency advantages and the SCE control advantages of finFET devices are likely to be of continued significance within semiconductor device technology. In addition, novel semiconductor structures having enhanced functionality are also likely to continue to be advantageous within semiconductor device technology. Thus, it is desirable to use finFET structures as a basis for fabrication of novel semiconductor device structures with enhanced functionality.

### SUMMARY OF THE INVENTION

The invention provides semiconductor structures and a method for fabricating a semiconductor structure. The structures and the method use a semiconductor fin analogous to that used in a conventional finFET device. A gate dielectric layer is located adjoining a first side of the semiconductor fin, and a control gate is located adjoining the gate dielectric layer. A tunneling dielectric layer is located adjoining a second (i.e., opposite the first) side of the semiconductor fin. A floating gate is located adjoining the tunneling gate dielectric layer, an intergate dielectric layer is located adjoining the floating gate electrode and a storage/programming gate electrode is located adjoining the intergate dielectric layer. The resulting semiconductor structure is a dual-function finFET structure that comprises a finFET structure laterally adjoining a semiconductor fin based non-volatile memory structure. The semiconductor fin based non-volatile memory structure comprises a broad aspect of the invention.

In accordance with the invention, one structure comprises a semiconductor fin located over a substrate. The semiconductor fin comprises a channel region used in a non-volatile memory structure that comprises the semiconductor structure.

In accordance with the invention, another structure also comprises a semiconductor fin located over a substrate. The semiconductor fin has a first side and a second side opposite the first side. The structure also comprises: (1) a gate dielectric layer located laterally adjoining the first side of the semiconductor fin; and (2) a control gate located further laterally adjoining the gate dielectric layer. Finally, the structure also comprises: (1) a tunneling dielectric layer located laterally adjoining the second side of the semiconductor fin; (2) a floating gate located further laterally adjoining the tunneling dielectric layer; (3) an intergate dielectric layer located further laterally adjoining the floating gate; and (4) a storage/programming gate located further laterally adjoining the intergate dielectric layer.

The method in accordance with the invention first provides for forming a semiconductor fin over a substrate. The semiconductor fin has a first side and a second side opposite the first side. The method also provides for forming a gate dielectric layer and a control gate over the substrate. The gate dielectric layer is located laterally adjoining the first side of the semiconductor fin and the control gate is located further laterally adjoining the gate dielectric layer. Finally, the method also provides for forming a tunneling dielectric layer, a floating gate, an intergate dielectric layer and a storage/programming gate over the substrate. The tunneling dielectric layer is located laterally adjoining the second side of the semiconductor fin, the floating gate is located further laterally adjoining the tunneling dielectric layer, the intergate dielectric layer is located further laterally adjoining the floating gate and the storage/programming gate is located further laterally adjoining the intergate dielectric layer.

Within the disclosed embodiment (and also the claimed invention), a “control gate” is intended as a gate used in a portion of a semiconductor fin based structure other than a non-volatile memory portion of the semiconductor fin based structure (i.e., as disclosed a control gate is intended to describe a gate electrode used within a more conventional finFET structure absent a non-volatile memory component). The disclosed embodiment (as well as the claimed invention) also uses the terminology “storage/programming gate” as a gate overlying a “floating gate” within the non-volatile memory portion of the semiconductor fin based structure. The above definitions for gates within the embodiment as disclosed, and invention as claimed, govern the embodiment as disclosed and the invention as claimed, although other intended uses for the same terminology may exist within other disclosures.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 27 show a series of schematic cross-sectional and plan-view diagrams illustrating the results of progressive stages in fabricating a semiconductor structure in accordance with a preferred embodiment of the invention.

### DESCRIPTION OF THE PREFERRED EMBODIMENT

The invention provides a dual function semiconductor structure that uses a semiconductor fin. The invention also provides a method for fabricating of the dual function semiconductor structure. The dual function semiconductor structure comprises a semiconductor fin. A first side of the semiconductor fin is used in a finFET structure. A second (i.e., opposite the first) side of the semiconductor fin is used in a semiconductor fin based non-volatile data storage structure.

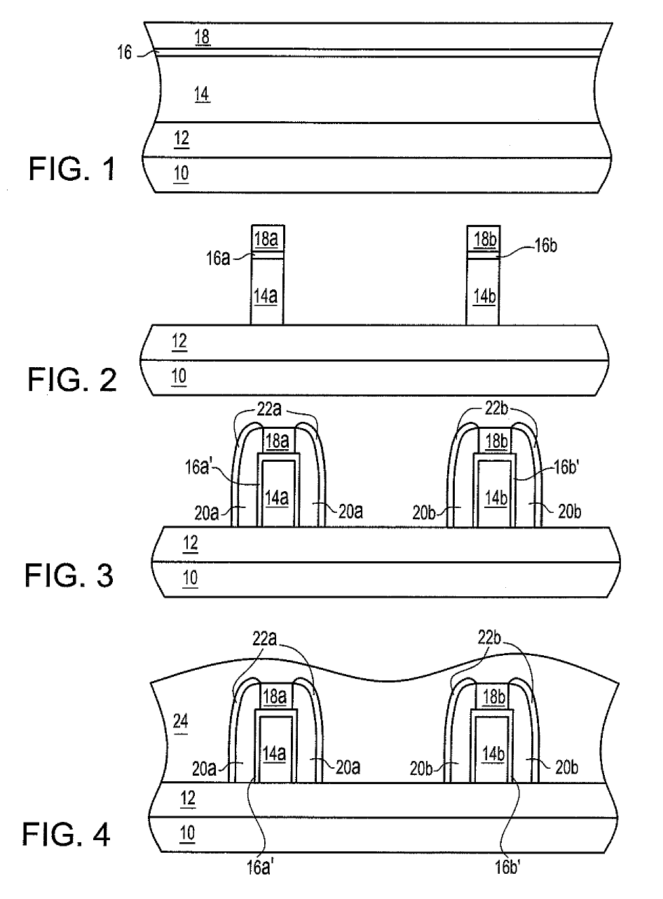

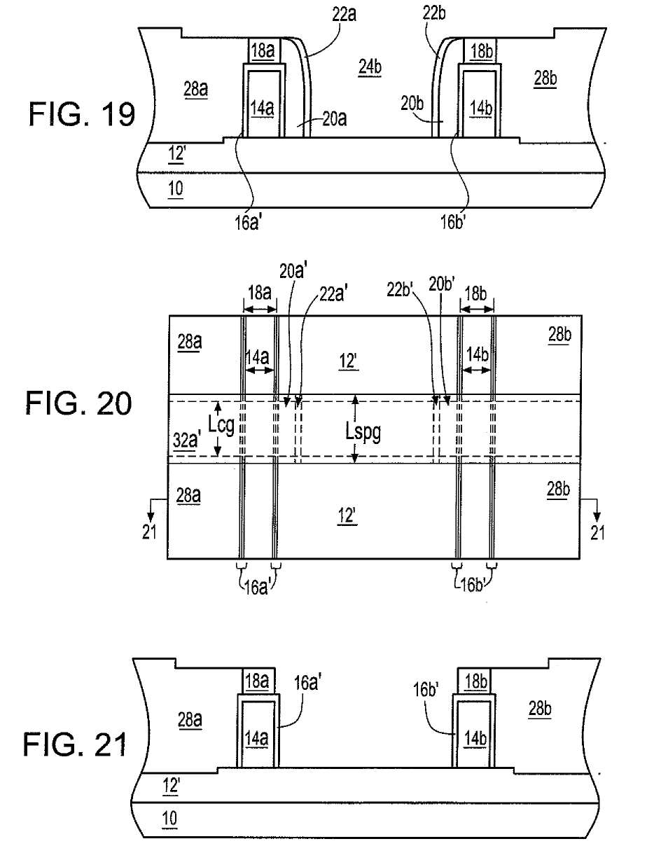

FIG. 1 to FIG. 27 show a series of schematic cross-sectional and plan-view diagrams illustrating the results of progressive stages in fabricating a dual function semiconductor structure in accordance with a preferred embodiment of the invention.

FIG. 1 shows a substrate 10. A buried dielectric layer 12 is located upon the substrate 10. A semiconductor layer 14 is located upon the buried dielectric layer 12. A blanket pad dielectric layer 16 is located upon the semiconductor layer 14. Finally, a blanket first hard mask layer 18 is located upon the blanket pad dielectric layer 16.

Each of the foregoing substrate 10 and layers may comprise materials and have dimensions that are conventional in the semiconductor fabrication art. Each of the foregoing substrate 10 and layers may also be formed using methods that are conventional in the semiconductor fabrication art.

The substrate 10 typically comprises a semiconductor material, although neither the embodiment nor the invention is limited to a substrate that comprises only a semiconductor material. The substrate 10 may alternatively comprise a conductor material and/or a dielectric material, either alone or in combination with a semiconductor material. Specific semiconductor materials may include, but are not limited to: silicon, germanium, silicon-germanium alloy, silicon carbide, silicon-germanium carbide alloy and compound (III-V and II-VI) semiconductor materials. Non-limiting examples of compound semiconductor materials include gallium arsenide, indium arsenide and indium phosphide semiconductor materials. Typically, the substrate 10 comprises a silicon or silicon-germanium alloy semiconductor material that has a thickness from about 1 to about 3 mils.

The buried dielectric layer 12 typically comprises a conventional dielectric material such as, but not limited to: an oxide, a nitride, an oxynitride or a composite thereof, typically of silicon and/or germanium, but other elemental oxides, nitrides and oxynitrides are not precluded. The buried dielectric 12 may be crystalline or non-crystalline depending upon the technique that was used in forming the same. Methods for fabrication of the buried dielectric layer 12 are disclosed in greater detail below. Typically, the buried dielectric layer 12 comprises a silicon oxide dielectric material that has a thickness from about 200 to about 2000 angstroms.

Similarly with the substrate 10, the semiconductor layer 14 may comprise any of several semiconductor materials. More particularly, the semiconductor layer 14 may comprise any of the semiconductor materials that are listed above, from which the substrate 10 may be comprised. Typically, the semiconductor layer 14 comprises a silicon or silicon-germanium alloy semiconductor material, although not necessarily of the same composition or crystallographic orientation as the substrate 10. Specific semiconductor materials may include, but are not limited to: silicon, germanium, silicon-germanium alloy, silicon carbide, silicon-germanium carbide alloy and compound (III-V and II-VI) semiconductor materials. Non-limiting examples of compound semiconductor materials include gallium arsenide, indium arsenide and indium phosphide semiconductor materials. Typically, the semiconductor layer 14 has a thickness from about 500 to about 2000 angstroms.

Under conditions when the substrate 10 comprises a semiconductor material, the substrate 10, the buried dielectric layer 12 and the semiconductor layer 14 comprise in an aggregate a semiconductor-on-insulator substrate. Within the semiconductor-on-insulator substrate, the substrate 10 and the blanket semiconductor layer 14 may (as noted above) comprise the same semiconductor material or a different semiconductor material (i.e, different with respect to either or both of chemical composition and crystallographic orientation). The semiconductor-on-insulator substrate may be formed using any of several methods that are conventional or unconventional in the semiconductor fabrication art. Non-limiting examples of methods include lamination methods, layer transfer methods and separation by implantation of oxygen (SIMOX) methods.

The blanket pad dielectric layer 16 may comprise any of several pad dielectric materials, but will typically comprise an oxide or an oxynitride pad dielectric material. Within the embodiment and the invention, the pad dielectric material is intended as a mechanical stress reducing material. The blanket pad dielectric layer 16 typically has a thickness from about 20 to about 70 angstroms. The blanket pad dielectric layer 16 may be formed using any of several methods. Non-limiting examples of methods include thermal oxidation methods, thermal nitridation methods, plasma oxidation or nitridation methods, chemical vapor deposition methods and physical vapor deposition methods. Thermal oxidation methods and plasma nitridation methods are common, but do not limit the invention.

The blanket first hard mask layer 18 typically comprises a dielectric hard mask material, although the invention does not preclude the use of semiconductor hard mask materials and conductor hard mask materials. When the blanket pad dielectric layer 16 comprises an oxide or an oxynitride dielectric material, the blanket first hard mask layer 18 generally comprises, respectively, an oxynitride or a nitride dielectric material that serves as a hard mask material. Typically, the blanket first hard mask layer 18 has a thickness from about 500 to about 1000 angstroms. Similarly with the blanket pad dielectric layer 16, the hard mask material used within the blanket first hard mask layer 18 may typically be formed using conventional methods. Non-limiting examples include chemical vapor deposition methods and physical vapor deposition methods.

FIG. 2 shows a pair of stack layers located upon the buried dielectric layer 12. A first of the pair of stack layers comprises: (1) a semiconductor fin 14a; (2) a patterned pad dielectric layer 16a located aligned thereupon; and (3) a patterned first hard mask layer 18a located aligned thereupon. A second of the pair of stack layers comprises: (1) a semiconductor fin 14b; (2) a patterned pad dielectric layer 16b located aligned thereupon; and (3) a patterned first hard mask layer 18b located aligned thereupon. The foregoing pair of stack layers results from a sequential patterning of the blanket first hard mask layer 18, the blanket pad dielectric layer 16 and the semiconductor layer 14.

The sequential patterning is effected while using as a mask a pair of patterned photoresist layers that is not otherwise shown in FIG. 2. The pair of patterned photoresist layers is used to pattern at least the blanket hard mask layer 18 to form the pair of patterned hard mask layers 18a and 18b. At least the pair of patterned hard mask layers 18a and 18b is used to pattern at least the blanket pad dielectric layer 16 and the blanket semiconductor layer 14 to provide the corresponding pair of patterned pad dielectric layers 16a and 16b and the corresponding pair of semiconductor fins 14a and 14b.

The foregoing patterning is typically effected while using an anisotropic etchant that is typically an anisotropic plasma etchant, so that sidewalls of the foregoing semiconductor fins 14a and 14b and patterned layers are vertical, or nearly so. Isotropic etchants will typically not provide a desired vertical sidewall profile. When etching a silicon containing semiconductor material, a chlorine containing etchant gas composition is typically used within a chlorine containing plasma etch method. When etching a silicon containing dielectric material, a fluorine containing etchant gas composition is typically used within a fluorine containing plasma etch method.

Finally, a typical linewidth of each of the foregoing semiconductor fins 14a and 14b, and the foregoing other patterned layers is from about 50 to about 100 nanometers (nm).

FIG. 3 first shows a pair of conformal contiguous first dielectric layers 16a′ and 16b′ located covering a pair of sidewall portions and a top portion of each of the pair of semiconductor fins 14a and 14b. Each of the pair of conformal contiguous first dielectric layers 16a′ and 16b′ incorporates each of the pair of corresponding patterned pad dielectric layers 16a and 16b. The pair of conformal contiguous first dielectric layers 16a′ and 16b′ may be formed using any of several methods, although as illustrated in FIG. 3 a thermal oxidation or otherwise selective deposition method is common. Other methods, that in general provide for independent deposition of a blanket dielectric layer that corresponds with the contiguous dielectric layer 16a′ or 16b′ may alternatively be used.

FIG. 3 also shows: (1) a pair of conductor spacer layers 20a located at opposite sides of the semiconductor fin 14a and the conformal contiguous first dielectric layer 16a′; and (2) a pair of conductor spacer layers 20b located at opposite sides of the semiconductor fin 14b and the conformal contiguous first dielectric layer 16b′. Finally, FIG. 3 shows: (1) a pair conformal second dielectric layers 22a located upon the pair of conductor spacer layers 20a; and (2) a pair of conformal second dielectric layers 22b located upon the pair of conductor spacer layers 20b.

The two pair of conductor spacer layers 20a and 20b may comprise any of several conductor materials. Non-limiting examples include metal, metal alloy, metal nitride, metal silicide, doped polysilicon (i.e., 1e18 to 1e20 dopant atoms per cubic centimeter) and polycide (doped polysilicon/metal silicide stack) conductor materials. Doped polysilicon is often a desirable conductor material. However, the invention is not limited to a doped polysilicon conductor material. Typically, the two pair of conductor spacer layers 20a and 20b comprise a doped polysilicon material. They are typically formed using a blanket layer deposition and anisotropic etchback method that is otherwise generally conventional in the semiconductor fabrication art. The blanket layer may be deposited using conventional methods, non-limiting examples of which include chemical vapor deposition methods and physical vapor deposition methods. The anisotropic etchback method will typically use a chlorine containing etchant gas composition, although the invention is not so limited.

The pair of conformal second dielectric layers 22a and 22b may comprise any of the dielectric materials from which the pair of conformal contiguous first dielectric layers 16a′ and 16b′ is comprised. The pair of conformal second dielectric layers 22a and 22b may also have thicknesses and be formed using methods analogous, equivalent or identical to the thicknesses and methods used with respect to the pair of conformal contiguous first dielectric layers 16a′ and 16b′. When the two pair of conductor spacer layers 20a and 20b comprise a doped polysilicon or doped polysilicon-germanium alloy material, the two pair of conformal second dielectric layers 22a and 22b are advantageously formed using a thermal oxidation method and/or a thermal nitridation method. Typically each of the two pair of conformal second dielectric layers 22a and 22b has a thickness from about 20 to about 70 angstroms.

FIG. 4 shows a blanket second conductor layer 24 located covering the semiconductor structure whose schematic cross-sectional diagram is illustrated in FIG. 3. The blanket second conductor layer 24 may comprise any of several conductor materials that are alternatively used for forming the two pair of conductor spacer layers 20a or 20b. As an arbitrary selection imposed to aid in effective further processing of the semiconductor structure of FIG. 3, the blanket second conductor layer 24 preferably comprises a silicon-germanium alloy conductor material (e.g., preferably having a germanium content from about 20 to about 30 atomic percent). Alternative arbitrary materials selections for the blanket second conductor layer 24 are also within the context of the invention. Typically, the blanket second conductor layer 24 has a thickness from about 1000 to about 1500 angstroms, but neither the embodiment nor the invention is so limited. Similarly with the two pair of conductor spacer layers 20a and 20b, the blanket second conductor layer 24 may be formed using generally conventional methods, non-limiting examples of which include chemical vapor deposition methods and physical vapor deposition methods.

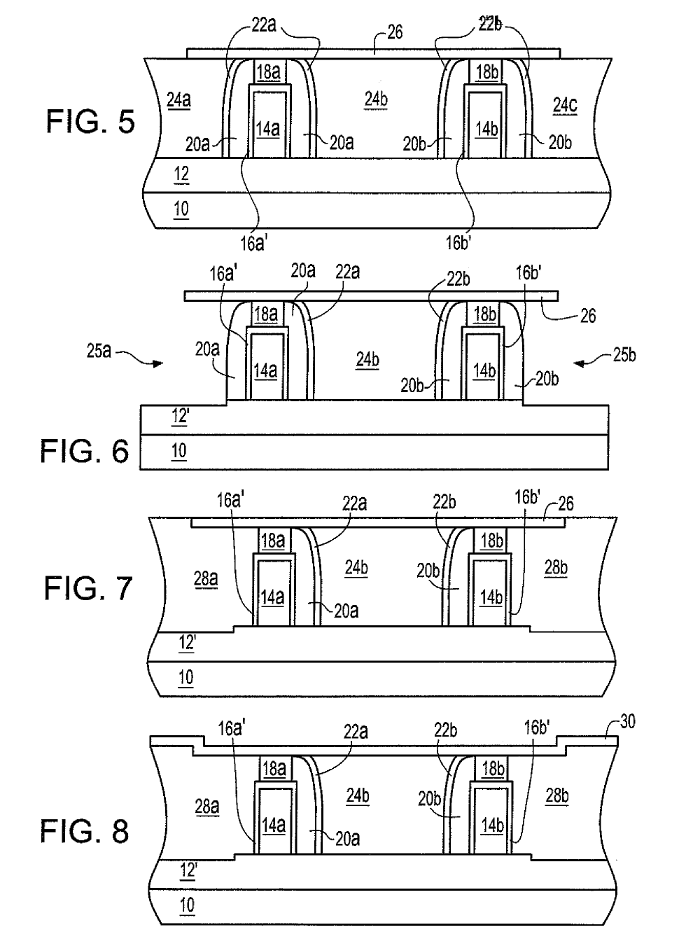

FIG. 5 shows a series of patterned second conductor layers 24a, 24b and 24c. The series of patterned second conductor layers 24a, 24b and 24c is formed incident to planarizing of the blanket second conductor layer 24 while using the pair of patterned first hard mask layers 18a and 18b as planarizing stop layers. The foregoing planarizing may be effected while using any of several planarizing methods. Non-limiting examples of planarizing methods include reactive ion etch etchback planarizing methods, mechanical planarizing methods and chemical mechanical polish (CMP) planarizing methods. Chemical mechanical polish planarizing methods are particularly common and efficient, but by no means limit the embodiment or the invention.

FIG. 5 also shows a patterned second hard mask layer 26 located spanning and fully covering the patterned second conductor layer 24b, and further spanning to partially cover each of the pair of patterned second conductor layers 24a and 24c, while leaving other major portions of the patterned second conductor layers 24a and 24c uncovered.

The patterned second hard mask layer 26 may comprise materials, have dimensions and be formed using methods, analogous, equivalent or identical to the materials, dimensions and methods used with respect to the blanket first hard mask layers 18 and patterned first hard mask layers 18a and 18b. Typically, the patterned second hard mask layer 26 comprises a nitride or an oxynitride hard mask material having a thickness from about 100 to about 200 angstroms.

FIG. 6 shows the results of stripping: (1) the pair of pair of patterned second conductor layers 24a and 24c; and (2) the outerlying pair of conformal second dielectric layers 22a and 22b from the semiconductor structure illustrated in FIG. 5. Stripping of the foregoing layers yields a pair of voids 25a and 25b, as illustrated in FIG. 6. Incident to stripping the pair of conformal second dielectric layers 22a and 22b, the buried dielectric layer 12 may also be etched to form an etched buried dielectric layer 12′. However, etching of the buried dielectric layer 12 to form the etched buried dielectric layer 12′ is not a necessary feature of the instant embodiment. Rather, the etching of the buried dielectric layer 12 to form the etched buried dielectric layer 12′ is an ancillary feature of the instant embodiment.

The foregoing layers may be stripped using methods and materials that are conventional in the semiconductor fabrication art. The methods and materials may include, but are not limited to: wet chemical methods and materials, dry plasma methods and materials and aggregate methods and materials thereof. Due to the overhang of the patterned second hard mask layer 26, wet chemical etchant methods and materials might be desirable since in the absence of directional substrate effects they are generally more isotropic. When comprised of a doped polysilicon-germanium alloy material, the pair of patterned second conductor layers 24a and 24c is nonetheless preferably etched and stripped using a plasma etch method that uses a fluorine containing etchant gas composition. Typical fluorine containing etchant gases are carbon tetrafluoride and trifluoromethane. Such plasma etchant gas compositions etch a silicon-germanium alloy material (at about 20 atomic percent germanium) with an etch specificity with respect to a silicon material from about 15:1 to about 30:1. When comprised of a silicon oxide material, the pair of patterned conformal second dielectric layers 22a and 22b is typically etched using an aqueous hydrofluoric acid etchant or an aqueous buffered hydrofluoric acid etchant.

FIG. 7 shows a pair of patterned third conductor layers 28a and 28b located approximately replacing the pair of patterned second conductor layers 24a and 24b, the outerlying pair of conformal second dielectric layers 22a and 22b and incorporating the outerlying pair of conductor spacer layers 20a and 20b that is illustrated in FIG. 5.

The pair of patterned third conductor layers 28a and 28b is comprised of a conductor material that has different etch characteristics from the conductor material that comprises the patterned second conductor layer 24b. Although any of several different choices thus exist for the pair of patterned third conductor layers 28a and 28b, they typically comprise a doped polysilicon conductor material when the patterned second conductor layer 24b comprises a doped polysilicon-germanium alloy conductor material. Etches that are specific to silicon-germanium alloy materials with respect to silicon materials are disclosed in further detail above. For specificity of silicon materials with respect to silicon-germanium alloy materials an aqueous tetramethylammonium hydroxide (TMAH) solution having a concentration from about 2 to about 10 weight percent may be used. The aqueous tetramethylammonium hydroxide solution has a selectivity for silicon materials with respect to silicon-germanium alloy materials of about 20:1 at a silicon-germanium alloy material germanium concentration of about 20 atomic percent.

The pair of patterned third conductor layers 28a and 28b is typically planarized from a blanket third conductor layer that is otherwise deposited upon the semiconductor structure whose schematic cross-sectional diagram is illustrated in FIG. 6 while completely filling the pair of voids 25a and 25b that are illustrated in FIG. 6. The planarization is typically effected while using the patterned second hard mask layer 26 as a planarizing stop layer. Non-limiting examples of planarizing methods include reactive ion etch etchback planarizing methods, mechanical polish planarizing methods and chemical mechanical polish planarizing methods. Again, chemical mechanical polish planarizing methods are common.

FIG. 8 first shows the results of stripping the patterned second hard mask layer 26 from the semiconductor structure of FIG. 7.

The patterned second hard mask layer 26 may be stripped from the semiconductor structure of FIG. 7 to provide the semiconductor structure of FIG. 8, while using methods and materials that are generally conventional in the art, and also appropriate to the composition of the patterned second hard mask layer 26. The methods and materials may include, but are not limited to: wet chemical methods and materials, dry plasma methods and materials and aggregate methods and materials thereof. When comprised of a silicon nitride material, the patterned second hard mask layer 26 may typically be efficiently stripped while using a phosphoric acid solution at elevated temperature.

FIG. 8 also shows a blanket third hard mask layer 30 located upon a top surface of the semiconductor structure of FIG. 7, after the patterned second hard mask layer 26 has been stripped therefrom. The blanket third mask layer 26 many comprise materials, have dimensions and be formed using methods analogous, equivalent or identical to the materials, dimensions and methods used for forming the patterned second hard mask layer 26, but with the exception that the blanket third hard mask layer 30 covers completely the surface of the semiconductor structure that is illustrated in FIG. 8.

Most typically, the blanket third hard mask layer 30 comprises a silicon nitride or a silicon oxynitride hard mask material that has a thickness from about 100 to about 200 angstroms. The blanket third hard mask layer 30 is typically formed using a chemical vapor deposition method, although other methods may also be used.

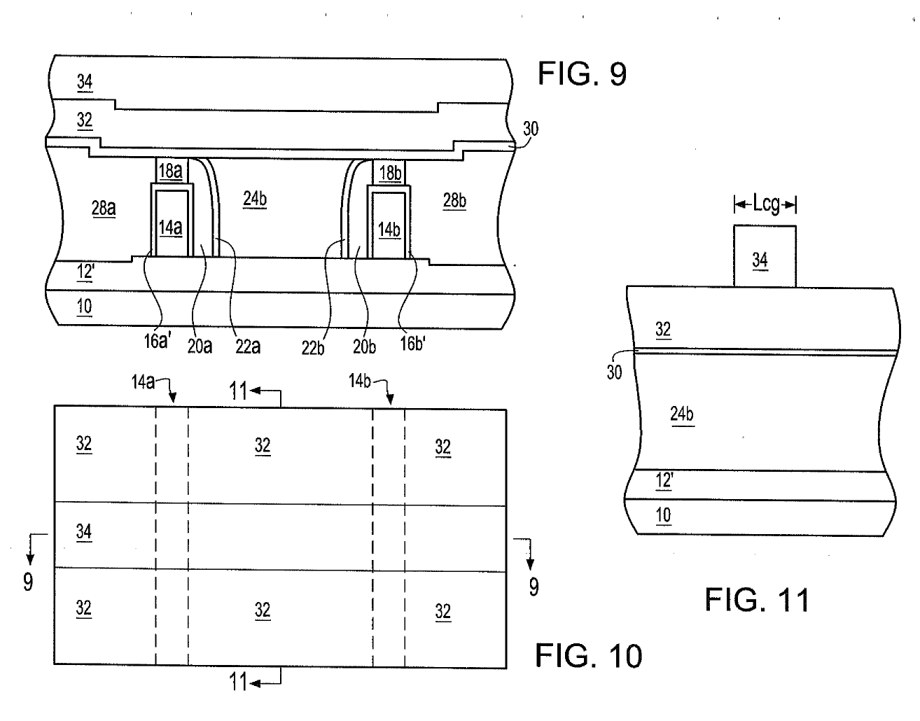

FIG. 9 shows a blanket fourth hard mask layer 32 located and formed upon the blanket third hard mask layer 30. FIG. 9 also shows a patterned photoresist layer 34 located and formed upon the blanket fourth hard mask layer 32.

The blanket fourth hard mask layer 32 comprises a hard mask material that has different etch characteristics than the hard mask material from which is comprised the blanket third hard mask layer 30. Any of several hard mask materials may be used, including but not limited to: conductor hard mask materials, semiconductor hard mask materials and dielectric hard mask materials, but dielectric hard mask materials are typically most common. When the blanket third hard mask material comprises a silicon nitride hard mask material, the blanket fourth hard mask layer typically comprises a silicon oxide hard mask material. Typically, the blanket fourth hard mask layer 32 has a thickness from about 300 to about 400 angstroms. The silicon oxide hard mask material is typically formed using a chemical vapor deposition method. Other methods may alternatively be used.

The patterned photoresist layer 34 may comprise photoresist materials that are conventional in the art. Such conventional photoresist materials may include, but are not limited to: positive photoresist materials, negative photoresist materials and hybrid photoresist materials. Typically the patterned photoresist layer 34 has a thickness from about 500 to about 2000 angstroms. The patterned photoresist layer 34 is typically formed using spin coating, photoexposure and development methods that are also otherwise generally conventional in the semiconductor fabrication art.

FIG. 10 shows a schematic plan-view diagram corresponding with the schematic cross-sectional diagram of FIG. 9.

For reference purposes, FIG. 10 shows only the locations of the pair of semiconductor fins 14a and 14b, and the patterned photoresist layer 34. Although the other structures that are illustrated in FIG. 9 are present also within FIG. 10, they have been omitted for clarity. FIG. 10 shows: (1) the pair of semiconductor fins 14a and 14b located beneath the blanket fourth hard mask layer 32, and (2) the patterned photoresist layer 34 located above the blanket fourth hard mask layer 32.

FIG. 11 shows a different cross-sectional diagram (i.e., a different cross-sectional plane in comparison with the cross-sectional diagram of FIG. 9), of the semiconductor structure whose schematic plan-view diagram is illustrated in FIG. 10.

FIG. 11 shows the substrate 10, the etched buried dielectric layer 12′, the patterned second conductor layer 24b, the blanket third hard mask layer 30, the blanket fourth hard mask layer 32 and the patterned photoresist layer 34. A linewidth of the patterned photoresist layer 34 is intended to eventually define a linewidth of a control gate Lcg within a semiconductor structure in accordance with the instant embodiment.

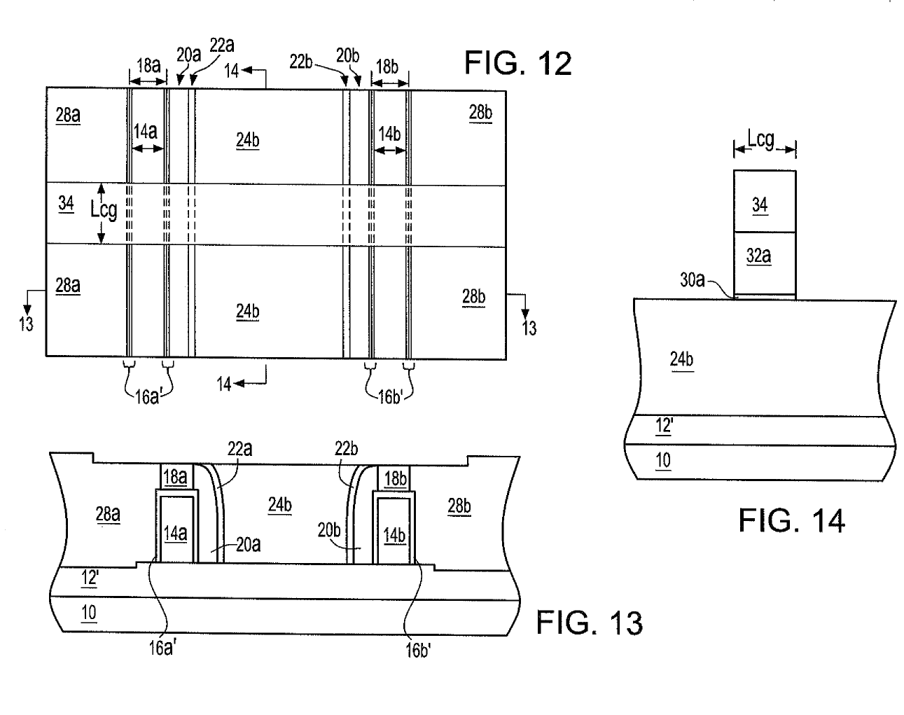

FIGS. 12-14 show a schematic plan-view diagram and a pair of schematic cross-sectional diagrams illustrating the results of further processing of the semiconductor structure whose schematic plan-view and schematic cross-sectional diagrams are illustrated in FIGS: 9-11.

As is illustrated most clearly within FIG. 14, each of FIGS. 12-14 illustrates the results of sequentially etching the blanket fourth hard mask layer 32 and the blanket third hard mask layer 30 while using the patterned photoresist layer 34 as an etch mask layer. The foregoing etching provides a corresponding patterned fourth hard mask layer 32a aligned upon a patterned third hard mask layer 30a.

The foregoing etching is typically an anisotropic etching that provides straight and aligned sidewalls for both the patterned fourth hard mask layer 32a and the patterned third hard mask layer 30a. When the blanket fourth hard mask layer 32 and the blanket third hard mask layer 30 comprise silicon containing hard mask materials (such as, respectively, a silicon oxide material and a silicon nitride material that may be etched with specificity with respect to each other in selected wet chemical etchants), they may nonetheless often be sequentially etched efficiently absent substantial selectivity while using a fluorine containing etchant gas composition. Typical fluorine containing etchant gases include, but are not limited to: perfluorocarbons, hydrofluorocarbons, nitrogen trifluoride and sulfur hexafluoride.

The schematic cross-sectional diagram of FIG. 13 shows a cross-sectional view of the semiconductor structure whose plan-view diagram is illustrated in FIG. 12 through a cross-sectional plane that illustrates absence of portions of the patterned third hard mask layer 30a and the patterned fourth hard mask layer 32a.

The schematic plan-view diagram of FIG. 12 shows all structures and features of the schematic cross-sectional diagrams of FIG. 13 and the schematic cross-sectional diagram of FIG. 14.

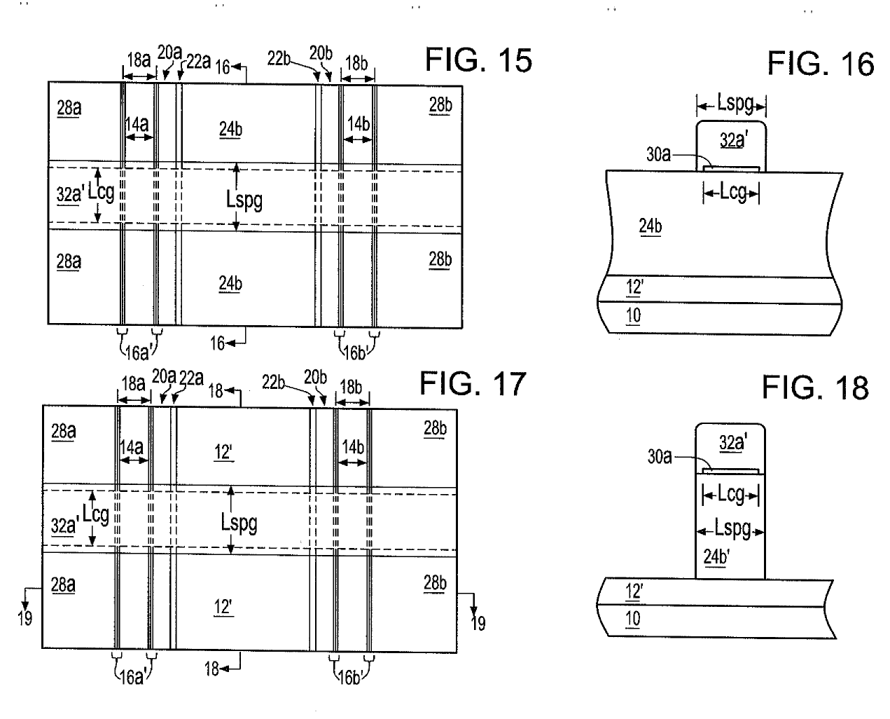

FIGS. 15-16 show a schematic plan-view and cross-sectional diagram illustrating the results of further processing of the semiconductor structure whose schematic plan-view and cross-sectional diagrams are illustrated in FIGS. 12-14.

As is illustrated more clearly in FIG. 16, the patterned photoresist layer 24 is first stripped from the patterned fourth hard mask layer 32. The patterned photoresist layer 34 may be striped using methods and materials that are conventional in the semiconductor fabrication art. Non-limiting examples include wet chemical stripping methods, dry plasma stripping methods and materials and aggregate stripping methods and materials thereof.

Although not specifically illustrated (but nonetheless illustrated by implication in FIG. 16), the patterned fourth hard mask layer 32 is then laterally augmented to provide the laterally augmented patterned fourth hard mask layer 32a′. The laterally augmented patterned fourth hard mask layer 32a′ has a wider linewidth than the patterned third hard mask layer 30a. The wider linewidth is intended to define the linewidth of a storage/programming gate Lspg within the semiconductor structure of the instant embodiment. Typically, the linewidth of the laterally augmented patterned fourth hard mask layer 32a′ is from about 200 to about 300 angstroms and the linewidth of the patterned third hard mask layer 30a is from about 150 to about 250 angstroms.

Typically, the laterally augmented patterned fourth hard mask layer 32a′ is formed using a blanket layer deposition and etchback method. The blanket layer is typically formed of the same hard mask material that is used for forming the patterned fourth hard mask layer 32, although such is not a specific requirement of the invention. Rather, the embodiment does, however, require that any and all materials components of the laterally augmented patterned fourth hard mask layer 32a′ have an etch specificity in a given particular etchant so that they may be selectively stripped from the patterned third hard mask layer 30a while not affecting a linewidth difference between the patterned third hard mask layer 30a and the laterally augmented patterned fourth hard mask layer 32a′.

Typically, the blanket layer used for forming the laterally augmented patterned fourth hard mask layer 32a′ is etched back to effectively provide a pair of spacers adjoining a pair of opposite sidewalls of the patterned fourth hard mask layer 32. The pair of spacers comprises the same material that comprises the patterned fourth hard mask layer 32.

FIGS. 17-19 show a series of schematic cross-sectional and plan-view diagrams illustrating the results of further processing of the semiconductor structure whose schematic cross-sectional and plan-view diagrams are illustrated in FIGS. 15-16.

As is illustrated most specifically in FIG. 18, the patterned first conductor layer 24b is patterned to form a storage/programming gate 24b′ while using the laterally augmented patterned fourth hard mask layer 32a′ as a mask. The etched semiconductor substrate 12′ is used as an etch stop layer. The etching may be undertaken while using a plasma etch method that uses a fluorine containing etchant gas composition having the specificity as described above for etching a silicon-germanium alloy material with respect to a silicon material.

FIGS. 20-21 shows the results of further sequential etching of the conformal second dielectric layers 22a and 22b, and the conductor spacer layers 20a and 20b to provide a corresponding pair of intergate dielectric layers 22a′ and 22b′ and a corresponding pair of floating gates 20a′ and 20b′. The sequential etching also uses the laterally augmented patterned fourth hard mask layer 32a′ as a mask, and the etched buried dielectric layer 12′ as a stop layer. Although the etching may under certain materials compositions provide for additional etching of the etched buried dielectric layer 12′, such is not illustrated in FIGS. 20-21, nor is the same considered a feature of the embodiment.

The etching may be effected while using wet chemical etch methods, dry plasma etch methods or aggregate methods thereof. When comprised of silicon oxide materials, the pair of conformal second dielectric layers 22a and 22b may often be efficiently etched to provide the pair of intergate dielectric layers 22a′ and 22b′ while using an aqueous hydrofluoric acid etchant. When comprised of a polysilicon material, the pair of conductor spacer layers 20a and 20b may be etched to provide the pair of floating gates while using a plasma etch method that uses a chlorine containing etchant gas composition. Alternatively, a tetramethylammonium hydroxide wet chemical etchant as disclosed above may also be used. The foregoing etch methods are merely exemplary and non-inclusive. They do not limit the invention.

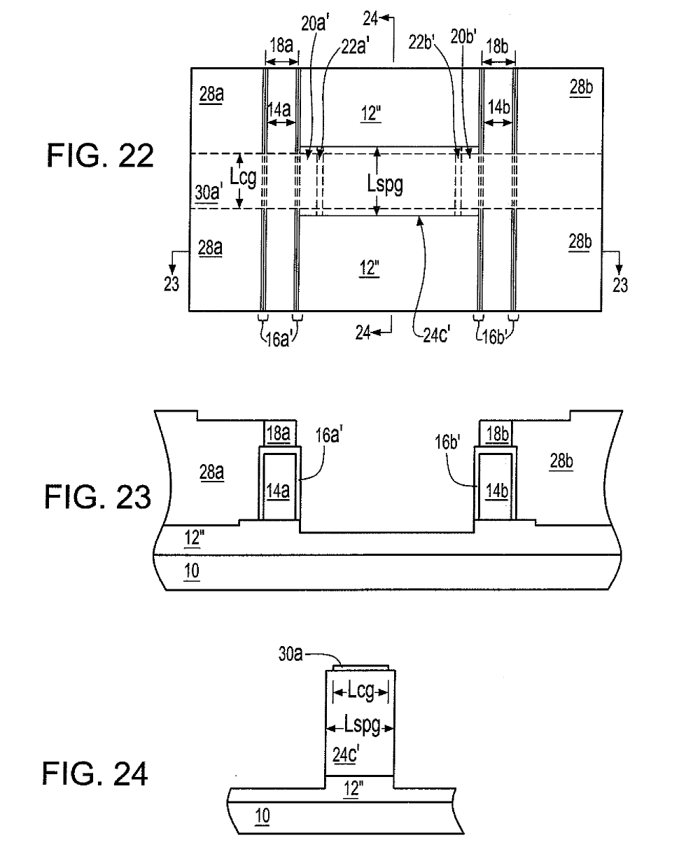

FIGS. 22-24 show a series of schematic cross-sectional and plan-view diagrams illustrating the results of further processing of the semiconductor structure whose schematic cross-sectional and plan-view diagrams are illustrated in FIGS. 20-21. FIGS. 22-24 show the results of stripping the laterally augmented patterned fourth hard mask layer 32a′ from the patterned third hard mask layer 30a.

The laterally augmented patterned fourth hard mask layer 32a′ may be striped using methods and materials that are conventional in the semiconductor product fabrication art. When the laterally augmented patterned fourth hard mask layer 32a comprises an oxide material and the buried dielectric layer 12 also comprises an oxide material, the etched buried dielectric layer 12′ is further etched to provide a further etched buried dielectric layer 12″ that is illustrated in FIGS. 22-24. Alternative materials selections may avoid further etching of the etched buried dielectric layer 12′ to provide the further etched buried dielectric layer 12″.

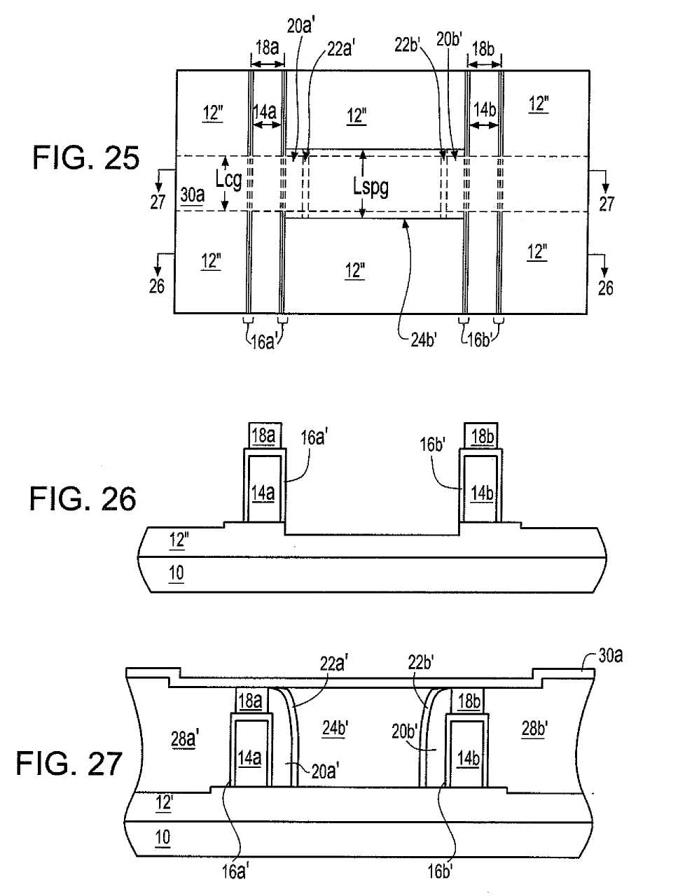

FIGS. 25-27 show a series of schematic cross-sectional and plan-view diagrams illustrating the results of further processing of the semiconductor structure whose schematic cross-sectional and plan-view diagrams are illustrated in FIGS. 22-24.

FIGS. 25-27 show the results of etching the pair of patterned third conductor layers 28a and 28b while using only the patterned third hard mask layer 30a as a mask, to provide a pair of control gates 28a′ and 28b′.

As is illustrated most clearly within the schematic plan-view diagram of FIG. 25, the etching exposes additional portions of the twice etched buried dielectric layer 12″. The etching is effected while using an etchant that has a specificity for etching a silicon material from which might preferably be comprised the patterned third conductor layers 28a and 28b, in comparison with a polysilicon-germanium alloy material from which might be comprised the storage/programming gate 24b′. As disclosed above, such an etchant may comprise an aqueous tetramethylammonium hydroxide solution.

FIGS. 25-27 show a series of schematic cross-sectional and plan-view diagrams illustrating a pair of dual function finFET structures in accordance with an embodiment of the invention. The pair of dual function finFET structures comprises a pair of semiconductor fins 14a and 14b. Located laterally adjoining one side of each of the semiconductor fins 14a and 14b is a portion of a contiguous conformal first dielectric layer 16a′ or 16b′ that serves as a gate dielectric layer. Further laterally adjoining each of the pair of gate dielectric layer portions of the conformal contiguous first dielectric layers 16a′ and 16b′ is a corresponding control gate 28a′ or 28b′. Located laterally adjoining a second side of each of the semiconductor fins 14a and 14b (i.e., opposite the first side of the pair of semiconductor fins 14a and 14b) is a second portion of each of the conformal contiguous first dielectric layers 16a′ and 16b′ that serves as a tunneling dielectric layer. Located further laterally adjoining the pair of tunneling dielectric layers is a pair of floating gates 20a′ and 20b′. Located further laterally adjoining the pair of floating gate electrodes 20a′ and 20b′ is a pair of intergate dielectric layers 22a′ and 22b′. Finally, located further laterally adjoining the pair of intergate dielectric layers 22a′. and 22b′ is a storage/programming gate 24b′.

Each of the pair of dual function finFET structures that is illustrated in FIGS. 25-27 includes: (1) a generally conventional finFET structure that may provide a switching function (e.g., semiconductor fin 14a or 14b, control gate 28a′ or 28b′ and the portion of the conformal contiguous first dielectric layer 16a′ or 16b′ located interposed therebetween); as well as (2) a non-volatile finFET structure that may provide a data storage function (e.g., semiconductor fin 14a or 14b, floating gate electrode 20a′ or 20b′, the portion of the conformal contiguous first dielectric layer 16a′ or 16b′ located interposed therebetween, the intergate dielectric layers 22a′ or 22b′ and the storage/programming gate 24b′.

A dual function finFET structure in accordance with the invention is fabricated using a processing scheme that provides for a control gate that has a narrower linewidth dimension than a storage/programming gate or a floating gate.

The preferred embodiment of the invention is illustrative of the invention rather than limiting of the invention. Revisions and modifications may be made to methods, materials, structures and dimensions of a dual finFET structure in accordance with the preferred embodiment of the invention while still providing a dual function finFET structure in accordance with the invention, further in accordance with the accompanying claims.

What is claimed is:

1. A semiconductor structure comprising a semiconductor fin located over a substrate, where the semiconductor fin comprises a channel region of a non-volatile memory structure that comprises the semiconductor structure.

2. The semiconductor structure of claim 1 wherein the channel region of the non-volatile memory structure comprises a second side of the semiconductor fin opposite a first side of the semiconductor fin.

3. The semiconductor structure of claim 2 further comprising a tunneling dielectric layer located laterally adjoining the second side of the semiconductor fin, a floating gate located further laterally adjoining the tunneling dielectric layer, an intergate dielectric layer located further laterally adjoining the floating gate and a storage/programming gate located further laterally adjoining the intergate dielectric layer.

4. The semiconductor structure of claim 3 further comprising a gate dielectric layer located laterally adjoining the first side of the semiconductor fin and a control gate located further laterally adjoining the gate dielectric layer.

5. The semiconductor structure of claim 4 wherein the control gate has a narrower linewidth than the storage/programming gate.

6. The semiconductor structure of claim 4 wherein the semiconductor fin comprises a semiconductor material selected from the group consisting of silicon, germanium, silicon-germanium alloy, silicon carbide, silicon-germanium carbide alloy, gallium arsenide, indium arsenide, indium phosphide and other compound semiconductor materials.

7. A semiconductor structure comprising:
a semiconductor fin located over a substrate and having a first side and a second side opposite the first side;
a gate dielectric layer located laterally adjoining the first side of the semiconductor fin and a control gate located further laterally adjoining the gate dielectric layer; and
a tunneling dielectric layer located laterally adjoining the second side of the semiconductor fin, a floating gate located further laterally adjoining the tunneling dielectric layer, an intergate dielectric layer located further laterally adjoining the floating gate and a storage/programming gate located further laterally adjoining the intergate dielectric layer.

8. The semiconductor structure of claim 7 wherein the control gate has a narrower linewidth than the storage/programming gate.

9. The semiconductor structure of claim 7 wherein the control gate has a narrower linewidth than the floating gate.

10. The semiconductor structure of claim 7 wherein the semiconductor fin comprises a semiconductor material selected from the group consisting of silicon, germanium, silicon-germanium alloy, silicon carbide, silicon-germanium carbide alloy, gallium arsenide, indium arsenide, indium phosphide and other compound semiconductor materials.

11. The semiconductor structure of claim 7 wherein the control gate and the storage/programming gate comprise different conductor materials.

12. The semiconductor structure of claim 7 wherein the floating gate and the storage/programming gate comprise a single conductor material.

13. The semiconductor structure of claim 7 wherein the gate dielectric layer is contiguous with the tunneling dielectric layer.

14. A method for fabricating a semiconductor structure comprising:
forming a semiconductor fin over a substrate, the semiconductor fin having a first side and a second side opposite the first side;
forming a gate dielectric layer and a control gate over the substrate, the gate dielectric layer being located laterally adjoining the first side of the semiconductor fin and the a control gate being located further laterally adjoining the gate dielectric layer; and
forming a tunneling dielectric layer, a floating gate, an intergate dielectric layer and a storage/programming gate over the substrate, the tunneling dielectric layer being located laterally adjoining the second side of the semiconductor fin, the floating gate being located further laterally adjoining the tunneling dielectric layer, the intergate dielectric layer being located further laterally adjoining the floating gate and the storage/programming gate being located further laterally adjoining the intergate dielectric layer.

15. The method of claim 14 wherein the steps of forming the control gate and forming the storage/programming gate comprise forming the control gate with a narrower linewidth than the storage/programming gate.

16. The method of claim 14 wherein the steps of forming the control gate and forming the floating gate comprise forming the control gate with a narrower linewidth than the floating gate.

17. The method of claim 14 wherein the step of forming the semiconductor fin over the substrate comprises forming the semiconductor fin that comprises a semiconductor material selected from the group consisting of silicon, germanium, silicon-germanium alloy, silicon carbide, silicon-germanium carbide alloy, gallium arsenide, indium arsenide, indium phosphide and other compound semiconductor materials over the substrate.

18. The method of claim 14 wherein the step of forming the control gate and forming the storage/programming gate comprise forming the control gate and forming the storage/programming gate of different materials.

19. The method of claim 14 wherein the steps of forming the control gate and forming the storage/programming gate comprise forming the floating gate and the storage/programming gate of the same conductor material.

20. The method of claim 14 wherein the steps of forming the gate dielectric layer and forming the tunneling dielectric layer comprise forming the gate dielectric layer contiguous with the tunneling dielectric layer.
